(19) United States
(12) Patent Application Publication
(10) Pub. No.: US 2009/0174996 A1
(43) Pub. Date: Jul. 9, 2009

(54) DISPLAY DEVICE

(76) Inventor: Sung-Jae Park, Seoul (KR)

Correspondence Address: F. CHAU & ASSOCIATES, LLC, 130 WOODBURY ROAD, WOODBURY, NY, 11797, US

(21) Appl. No.: 12/200,715

(22) Filed: Aug. 28, 2008

(30) Foreign Application Priority Data
Jan. 3, 2008 (KR) 10-2008-0000802

(51) Int. Cl. G06F 1/16; H05K 7/14

(52) U.S. Cl. 361/679.21

(57) ABSTRACT

A display device which can securely receive a display panel and an optical sheet therein and prevent a dark area from being formed on the display panel due to an intermediate frame. The display device includes a display panel displaying images, a guide member including a plurality of sidewalls and a flange which extends from an inner surface of each sidewall and on which the display panel is placed, and an optical sheet disposed under the flange, wherein the flange includes a top surface, which contacts the display panel, and a bottom surface which contacts the optical sheet, and the bottom surface of the flange extends further from the inner surface of each sidewall than the top surface of the flange.

### CROSS-REFERENCE TO RELATED APPLICATION

This application claims priority from Korean Patent Application No. 10-2008-0000802 filed on Jan. 3, 2008 in the Korean Intellectual Property Office, the disclosure of which is incorporated herein by reference in its entirety.

### BACKGROUND OF THE INVENTION

1. Technical Field

The present invention relates to a display device, and more particularly, to a display device which can securely receive a display panel and an optical sheet therein and prevent a dark area from being formed on the display panel due to an intermediate frame.

2. Discussion of the Related Art

As modern society becomes more dependent on sophisticated information and communication technology, the market needs for larger and thinner displays are growing. In particular, since conventional cathode ray tubes (CRTs) have failed to fully satisfy these market needs, the demand for flat panel displays (FPDs), such as plasma display panels (PDPs), plasma address liquid crystal display panels (PALCs), liquid crystal displays (LCDs), and organic light emitting diodes (OLEDs), is increasing.

Being low power-consuming, light, and compact, LCDs are widely applied in computer, electronics, and information and technology (IT) industries. A conventional LCD includes a liquid crystal panel assembly having a liquid crystal panel which displays image information, a backlight assembly having a light-emitting device and a light guide panel which guides light toward the liquid crystal panel, and a case receiving the liquid crystal panel assembly and the backlight assembly therein.

The size, shape and position of parts included in the LCD may affect images displayed on the liquid crystal panel. Therefore, the shape of each part can be designed to enhance the quality of images displayed on the liquid crystal panel.

### SUMMARY OF THE INVENTION

Embodiments of the present invention provide a display device which can securely receive a display panel and an optical sheet therein and prevent a dark area from being formed on the display panel due to an intermediate frame.

According to an embodiment of the present invention, a display device includes a display panel displaying images, a guide member including a plurality of sidewalls and a flange which extends from an inner surface of each sidewall and on which the display panel is placed, and an optical sheet disposed under the flange, wherein the flange includes a top surface, which contacts the display panel, and a bottom surface which contacts the optical sheet, and the bottom surface of the flange extends further from the inner surface of each sidewall than the top surface of the flange.

According to an embodiment of the present invention, a display device includes a display panel displaying images, a guide member including a plurality of sidewalls and a flange which extends from an inner surface of each sidewall and on which the display panel is placed, and an optical sheet disposed under the flange, wherein the flange includes a top surface, which contacts the display panel, and a bottom surface, which is opposite the top surface and contacts the optical sheet, and a recess forming a space between the top surface and the bottom surface and, wherein the recess is recessed toward each sidewall.

According to an embodiment of the present invention, a display device includes a display panel displaying images, a guide member including a plurality of sidewalls and a plurality of flanges which protrude from inner surfaces of the sidewalls, respectively, and on which the display panel is placed, and an optical sheet disposed under the flanges, wherein the flanges are separated from one another by a predetermined gap.

### BRIEF DESCRIPTION OF THE DRAWINGS

The above and other aspects and features of the present invention will become more apparent by describing in detail exemplary embodiments thereof with reference to the attached drawings, in which:

FIG. 1 is a perspective view of a liquid crystal display (LCD) according to an exemplary embodiment of the present invention;

FIG. 2 is an exploded perspective view of the LCD of FIG. 1;

FIG. 3 is a partial perspective view of an intermediate frame included in the LCD of FIG. 1;

FIG. 4A is a cross-sectional view of the LCD taken along a line IV-IV′ of FIG. 1;

FIG. 4B is an enlarged view of a region A shown in FIG. 4A;

FIG. 5 is a partial perspective view of an intermediate frame included in an LCD according to an exemplary embodiment of the present invention;

FIG. 6 is a cross-sectional view of the intermediate frame taken along a line VI-VI′ of FIG. 5;

FIG. 7 is a partial perspective of an intermediate frame included in an LCD according to an exemplary embodiment of the present invention;

FIG. 8 is a cross-sectional view of the intermediate frame taken along a line VIII-VIII′ of FIG. 7;

FIG. 9 is a plan view of an intermediate frame in an LCD according to an exemplary embodiment of the present invention;

FIG. 10 is a partial perspective of the intermediate of FIG. 9; and

FIG. 11 is a cross-sectional view of the intermediate frame taken along a line XI-XI′ of FIG. 9.

### DETAILED DESCRIPTION OF THE INVENTION

Embodiments of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Like reference numerals may refer to like elements throughout the specification.

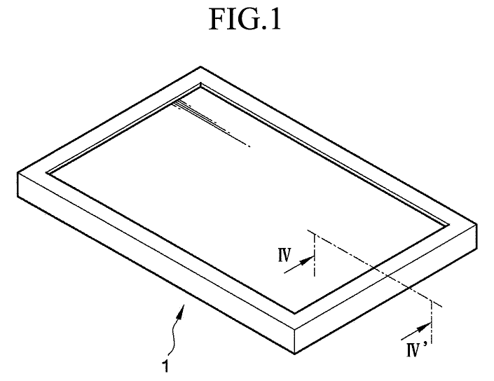

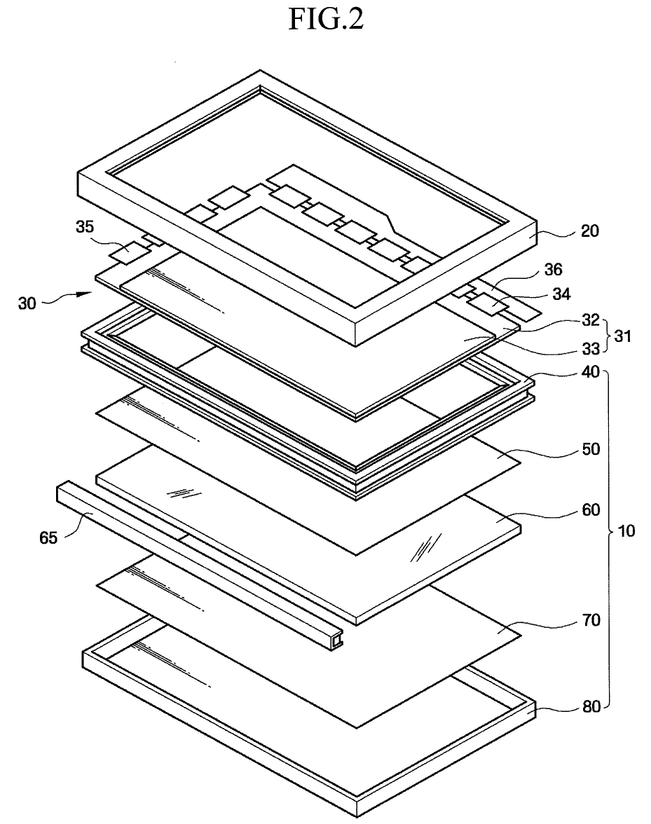

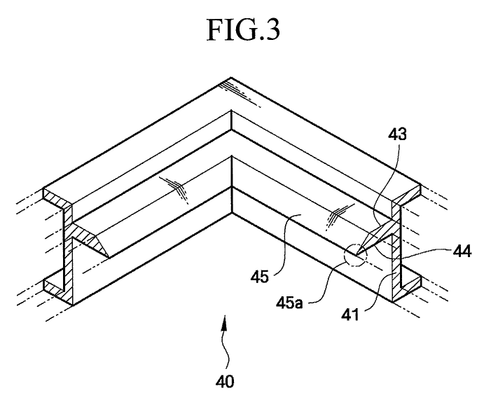

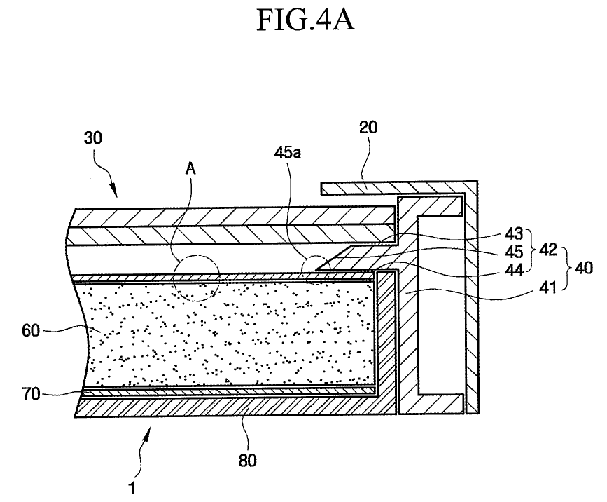

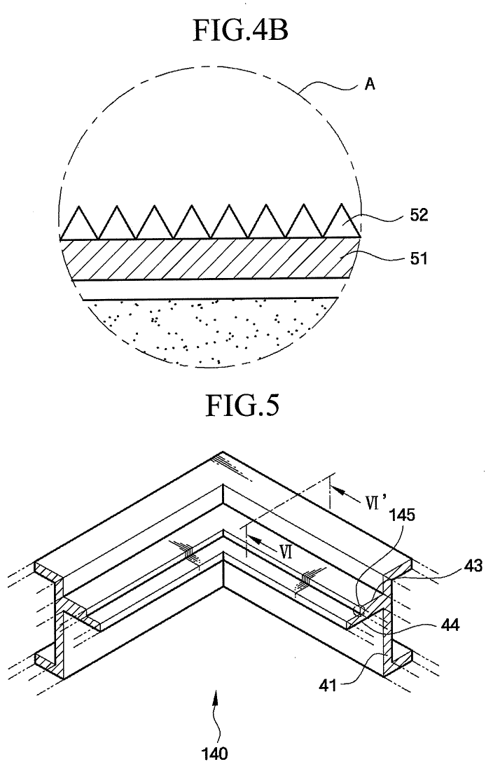

A liquid crystal display (LCD) according to an exemplary embodiment of the present invention will be described with reference to FIGS. 1 through 4B. FIG. 1 is a perspective view of an LCD 1 according to an exemplary embodiment of the present invention. FIG. 2 is an exploded perspective view of the LCD 1 of FIG. 1. FIG. 3 is a partial perspective view of an intermediate frame 40 included in the LCD 1 of FIG. 1. FIG. 4A is a cross-sectional view of the LCD 1 taken along a line IV-IV′ of FIG. 1. FIG. 4B is an enlarged view of a region A shown in FIG. 4A.

Referring to FIGS. 1 through 4B, the LCD 1 according to an exemplary embodiment of the present invention includes a liquid crystal panel assembly 30, an upper case 20, and a backlight assembly 10.

The liquid crystal panel assembly 30 includes a liquid crystal panel 31, which has a lower display substrate 32 and an upper display substrate 33, liquid crystals (not shown), a gate chip film package 35, a data chip film package 34, and a printed circuit board (PCB) 36.

The liquid crystal panel 31 includes the lower display substrate 32 and the upper display substrate 33 which faces the lower display substrate 32. The lower display substrate 32 includes gate lines (not shown), data lines (not shown), a thin-film transistor (TFT) array, and pixel electrodes. The upper display substrate 33 includes a color filter, a black matrix and common electrodes. The color filter and the common electrodes may also be formed on the lower display substrate 32.

The gate chip film package 35 is connected to each gate line (not shown) formed on the lower display substrate 32, and the data chip film package 34 is connected to each data line (not shown) formed on the lower display substrate 32. Each of the gate chip film package 35 and the data chip film package 34 includes a wiring pattern, in which semiconductor chips are formed on a base film, and a tape automated bonding (TAB) tape which is bonded with the semiconductor chips by TAB technology. Each of the gate chip film package 35 and the data chip film package 34 may be, for example, a tape carrier package (TCP) or a chip on film (COF), but is not limited thereto.

A number of driving parts are mounted on the PCB 36 to transmit a gate-driving signal to the gate chip film package 35 and a data-driving signal to the data chip film package 34.

The upper case 20 forms the exterior of the LCD 1 and has space in which the liquid crystal assembly 30 is accommodated. An open window is formed in the center of the upper case 20 to expose the liquid crystal panel 31. The upper case 20 is coupled to a lower case 80 with the intermediate frame 40 interposed therebetween.

The backlight assembly 10 includes the intermediate frame 40, an optical sheet 50, a light guide panel 60, a light-emitting device 65, and a reflective sheet 70.

The light-emitting device 65 includes one or more light sources which emit light. Lamps used as the light sources may be line light sources, such as cold cathode fluorescent lamps (CCFLs), hot cathode fluorescent lamps (HCFLs) and external electrode fluorescent lamps (EEFLs), or point light sources such as light emitting diodes (LEDs). If the backlight assembly 10 is an edge-type backlight assembly as shown in FIG. 2, the light-emitting device 65 may be installed on one or more side surfaces of the light guide plate 60. That is, the light-emitting device 65 may be installed on a side surface of the light guide panel 60 or, when necessary, on both side surfaces of the light guide panel 60.

The light guide panel 60 guides light emitted from the light-emitting device 65 toward the liquid crystal panel assembly 30. The light guide panel 60 is made of a transparent plastic material such as acrylic and guides light emitted from the light sources toward the liquid crystal panel 31 which is disposed above the light guide panel 60. Therefore, various patterns may be printed on a bottom surface of the light guide panel 60 in order to guide light, which is incident to the light guide panel 60, toward the liquid crystal panel 31.

The reflective sheet 70 is installed under the light guide panel 60 and reflects light, which is emitted downward from the light guide panel 60, in an upward direction. The reflective sheet 70 is disposed under the light guide panel 60 and reflects light, which has not been reflected by patterns, for example, minute dot patterns, formed on the bottom surface of the light guide panel 60, toward an exit surface of the light guide panel 60. Therefore, the reflective sheet 70 reduces the loss of light, which is incident to the liquid crystal panel 31, and, at the same time, improves the uniformity of light which passes through the exit surface of the light guide panel 60. The reflective sheet 70 may be inserted as a separate sheet. Alternatively, the reflective sheet 70 may be a reflective pattern formed by coating a highly reflective material on the lower case 80.

The optical sheet 50 is disposed on the light guide panel 60 and diffuses and collects light from the light guide panel 60. The optical sheet 50 may be at least one of a diffusion sheet, a prism sheet and a protective sheet. Alternatively, the optical sheet 50 may function as the diffusion sheet, the prism sheet and the protective sheet. That is, the optical sheet 50 may include a diffusion sheet 51, which has a diffusion function, a prism pattern 52, which is formed on the diffusion sheet 51, and a protective layer (not shown) which is formed on the prism pattern 52. As described above, since the optical sheet 50 includes the diffusion sheet 51, which has the diffusion function, and the prism pattern 52 which provides an internal total reflection condition, the number of parts included the LCD 1 can be reduced. Consequently, the LCD 1 can become slimmer.

The intermediate frame 40 accommodates the optical sheet 50, the light guide panel 60, and the light-emitting device 65 and is firmly fixed to the lower case 80. An open window is formed in the center of the intermediate frame 40 to allow light that passed through the light guide panel 60 and the optical sheet 50 to also pass through the intermediate frame 40. The intermediate frame 40 includes sidewalls 41, which are formed along rectangular edges thereof, and a flange 42 which protrudes from each of the sidewalls 41 toward the center of the intermediate frame 40. The intermediate frame 40 maintains a predetermined gap between the liquid crystal panel 31 and the optical sheet 50 and functions as a guide member that supports the optical sheet 50, the light guide panel 60 and the light-emitting device 65. The intermediate frame 40 as a whole may be formed by a molding process. Alternatively, each of the sidewalls 41 may be separately formed by an injection-molding process.

The sidewalls 41 extend along the rectangular edges of the intermediate frame 40 to form four surfaces of the intermediate frame 40. The sidewalls 41 are formed to have a predetermined level of hardness to support the backlight assembly 10 and protect the liquid crystal panel assembly 30, the optical sheet 50, the light guide panel 60, the light-emitting device 65, and the reflective sheet 70 received inside the frame 40.

The flange 42 extends toward the center of the intermediate frame 40 from each of the sidewalls 41 and divides an inner surface of each of the sidewalls 41 into two parts, such as, for example, in halves. The liquid crystal panel 31 is disposed on the flange 42, and the optical sheet 50 and the light guide panel 60 are disposed under the flange 42. The flange 42 and the sidewalls 41 may be formed as a single component. Alternatively, flanges 42 may be formed separately from the sidewalls 41 and then coupled to each of the sidewalls 41.

The flange 42 protrudes from each of the sidewalls 41 toward the center of the intermediate frame 40 and is formed along the sidewalls 41. The distance by which the flange 42 protrudes from the sidewalls 41 may vary according to the size and weight of the liquid crystal panel 31. The flange 42 includes a top surface 43, a bottom surface 44, and an inclined portion 45. The liquid crystal panel 31 is placed on the top surface 43, and the optical sheet 50 contacts the bottom surface 44.

As described above, the flange 42 supports the liquid crystal panel 31 and fixes the optical sheet 50 and the light guide panel 60 thereunder. Thus, the width of the top surface 43 must be sufficient to support the liquid crystal panel 31, and that of the bottom surface 44 must be sufficient to prevent the disengagement of the optical sheet 50 from the lower case 80.

Since the liquid crystal panel 31 includes the upper display substrate 33 and the lower display substrate 32 which are insulating substrates and coupled to each other, the liquid crystal panel 31 is harder than the optical sheet 50. Therefore, even if the width of the top surface 43 is smaller than that of the bottom surface 44, the liquid crystal panel 31 can be securely placed on the top surface 43. That is, the width of the bottom surface 44 is greater than that of the top surface 43 in order to firmly fix the optical sheet 50, which is softer than the liquid crystal panel 31. As described above, the top surface 43 and the bottom surface 44 of the flange 42 may have different widths, and the inclined portion 45 may further be formed between the top and bottom surfaces 43 and 44 of the flange 42.

The inclined portion 45 maintains a sufficient gap between the liquid crystal panel 31 and the optical sheet 50 and connects the top surface 43 and the bottom surface 44 of the flange 42. If the inclined portion 45 is formed between the top surface 43 having a smaller width and the bottom surface 44 having a larger width, the cross section of an end 45a of the flange 42 is reduced. Therefore, the end 45a of the flange 42 can be prevented from being reflected in the liquid crystal panel 31 and thus seen through the liquid crystal panel 31. That is, if the width of the top surface 43 is equal to that of the bottom surface 44 and if a vertical surface is formed between the top and bottom surfaces 43 and 44, the cross section area of the end 45a reflected in the liquid crystal panel 31 may be wide. Therefore, the end 45a of the flange 42 may be seen through the liquid crystal panel 31, which, in turn, may deteriorate the display quality of the LCD 1.

However, in the intermediate frame 40 according to the an embodiment, an edge of the bottom surface 44 corresponds to the cross section of the end 45a of the flange 42. That is, since the cross section area of the end 45a of the flange 42 is minimized, the flange 42 can be prevented from being seen through the liquid crystal panel 31.

If the top surface 43 has a narrow width or if the top surface 43 is removed, the flange 42 may include only the bottom surface 44 and the inclined portion 45. That is, the flange 42 may gradually taper from a portion thereof, which is adjacent to the sidewalls 41, toward the end 45a thereof.

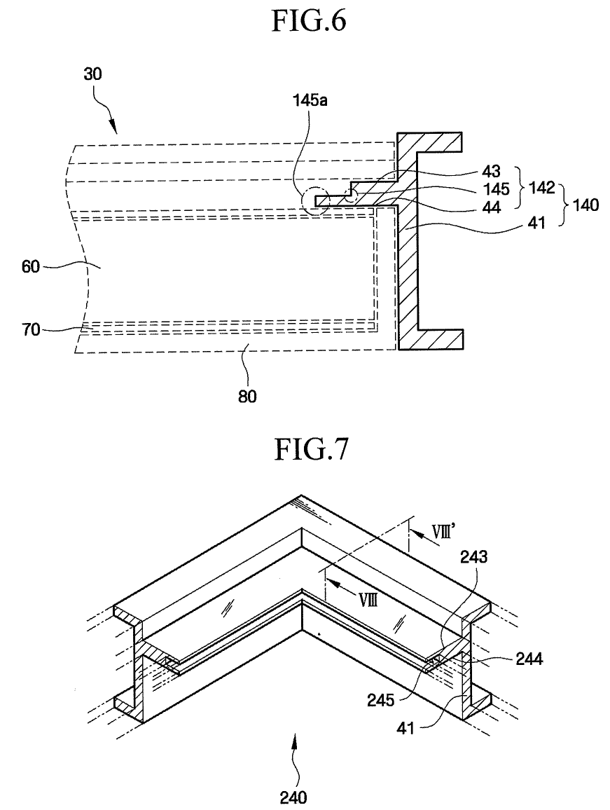

An LCD according to an exemplary embodiment of the present invention will be described with reference to FIGS. 5 and 6. FIG. 5 is a partial perspective view of an intermediate frame 140 included in an LCD 1 according to an exemplary embodiment of the present invention. FIG. 6 is a cross-sectional view of the intermediate frame 140 taken along a line VI-VI′ of FIG. 5.

The LCD 1 includes the intermediate frame 140 having a flange 142 including a step portion 145. The intermediate frame 140 includes sidewalls 41, which are formed along edges of the intermediate frame 140, and the flange 142, which extends toward the center of the intermediate frame 140 from each of the sidewalls 41. The flange 142 includes a top surface 43, a bottom surface 44, and the step portion 145 which is formed between the top and bottom surfaces 43 and 44.

As described above, the cross section of an end 145a of the flange 142 may be reduced in order to prevent the end 145a of the flange 142 from being seen through a liquid crystal panel 31. Accordingly, the width of the top surface 43 may be smaller than that of the bottom surface 44, and the step portion 145 may be formed between the top and bottom surfaces 43 and 44. In this case, the step portion 145 refers to one or more steps which connect the top and bottom surfaces 43 and 44 at different heights on the flange 142. The step portion 145 is formed as one or more steps that connect the top surfaces 43 and bottom surfaces 44 at different heights. In addition, the number of steps and the length and height of each step may be adjusted whenever necessary. The size of the flange 142 may vary according to the size, shape and weight of the liquid crystal panel 31 or the size and softness of an optical sheet 50. In addition, the length and thickness of the step portion 145 may vary according to the size of the flange 142.

Since the step portion 145 is formed in the flange 142, the cross section of the end 145a of the flange 142 can be reduced, and a sufficient gap can be secured between the top and bottom surfaces 43 and 44 of the flange 142. As a result, the liquid crystal panel 31 can be prevented from sinking and thus contacting the optical sheet 50. If the liquid crystal panel 31 sinks and thus contacts the optical sheet 50, it can damage the optical sheet 50 and deteriorate the display quality of the LCD 1.

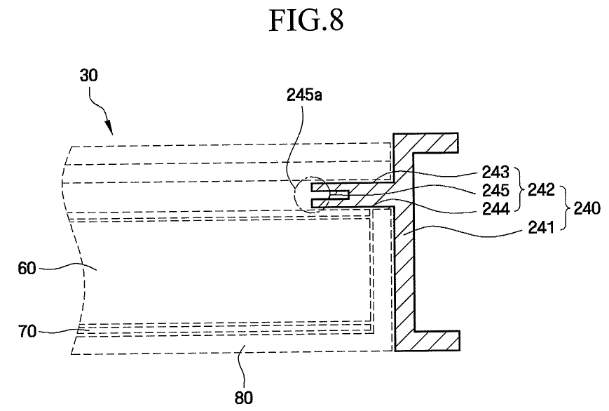

An LCD according to an exemplary embodiment of the present invention will be described with reference to FIGS. 7 and 8. FIG. 7 is a partial perspective of an intermediate frame 240 included in an LCD 1 according to an exemplary embodiment of the present invention. FIG. 8 is a cross-sectional view of the intermediate frame 240 taken along a line VIII-VIII′ of FIG. 7. The LCD 1 according to an exemplary embodiment of the present invention includes the intermediate frame 240 having a flange 242 including a recess 245. The intermediate frame 240 includes sidewalls 41, which are formed along edges of the intermediate frame 240, and the flange 242, which extends toward the center of the intermediate frame 240 from each of the sidewalls 41. The flange 242 includes a top surface 243, a bottom surface 244, and the recess 245 between the top and bottom surfaces 243 and 244.

As described above, the recess 245, which forms space between the top surface 243 and the bottom surface 244, is recessed toward each of the sidewalls 41, may be formed at an end 245a of the flange 242 in order to reduce the cross section of the end 245a of the flange 242. If the recess 245 is formed at the end 245a of the flange 242, the width of the top surface 243 may be equal to that of the bottom surface 244. If the width of the top surface 243 is equal to that of the bottom surface 244, a liquid crystal panel 31 can be firmly fixed to the top surface 243.

When necessary, the width of the top surface 243 may be reduced to be smaller than that of the bottom surface 244. For example, in order to reduce the cross-section of the end 245a of the flange 242, the width of the top surface 243 may be reduced to be smaller than that of the bottom surface 244, and the recess 245 may further be formed between the top and bottom surfaces 243 and 244 of the flange 242. If the width of the top surface 243 is smaller than that of the bottom surface 244 and if the recess 245 is formed between the top and bottom surfaces 243 and 244, the cross section of the end 245a of the flange 242 can be reduced, and a sufficient gap can be secured between the top and bottom surfaces 243 and 244 of the flange 242. Therefore, the liquid crystal panel 31 can be prevented from sinking and thus contacting an optical sheet 50. The depth of the recess 245 may vary according to the size and thickness of the liquid crystal panel 31.

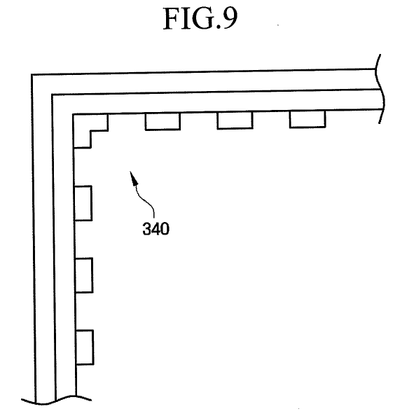

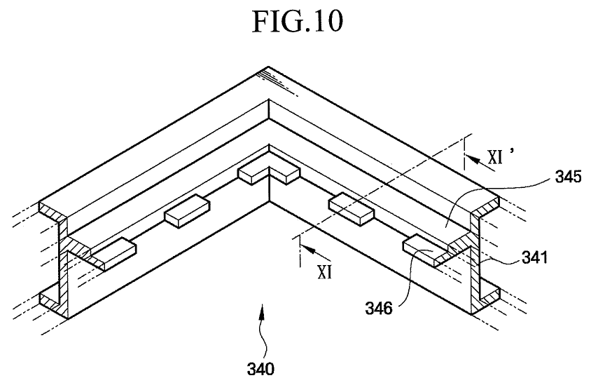

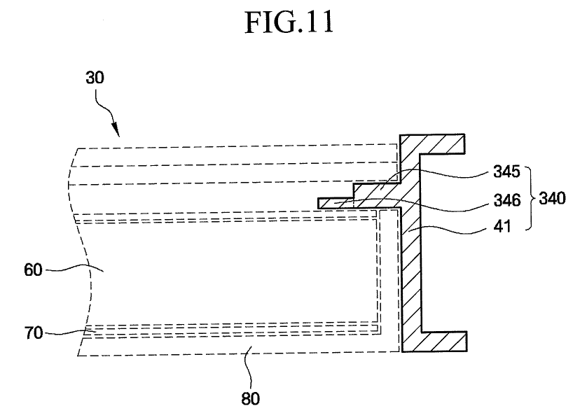

An LCD according to an exemplary embodiment of the present invention will be described with reference to FIGS. 9 through 11. FIG. 9 is a plan view of an intermediate frame 340 in an LCD 1 according to an exemplary embodiment of the present invention. FIG. 10 is a partial perspective of the intermediate 340 of FIG. 9. FIG. 11 is a cross-sectional view of the intermediate frame 340 taken along a line XI-XI′ of FIG. 9.

The LCD 1 according to an exemplary embodiment of the present invention includes the intermediate frame 340 having a flange 345 and a plurality of protrusions 346. The intermediate frame 340 includes sidewalls 41, which are formed along edges of the intermediate frame 340, and the flange 345 which extends toward the center of the intermediate frame 340 from each of the sidewalls 41. The protrusions 346 are formed to be spaced apart from each other along an end of the flange 345.

A liquid crystal panel 31 may be placed on a top surface of the flange 345, and the width of the flange 345 may be sufficient to accommodate the liquid crystal panel 31. In order to effectively fix an optical sheet 50, which is disposed under the flange 345, the protrusions 346, extending further toward the center of the intermediate frame 340 than the flange 345, are formed. A bottom surface of each protrusion 346 is on the same level as a bottom surface of the flange 345, and each protrusion 346 may be thinner than the flange 345.

The flange 345 is formed to accommodate the liquid crystal panel 31 on the top surface thereof. While the flange 345 and the protrusions 346 are described as separate components, the protrusions 346 may be a component of the flange 345 or a component added to the flange 345.

The protrusions 346 extend from the flange 345 to securely fix the optical sheet 50. As described above, since the optical sheet 50 is relatively softer than the liquid crystal panel 31, the bottom surface of the flange 346 is wider than the top surface thereof, on which the liquid crystal panel 31 is placed, in order to firmly fix the optical sheet 50. To this end, the protrusions 346 are formed to extend from the end of the flange 345 and fix the optical sheet 50. The bottom surface of the flange 345 may be on the same level as those of the protrusions 346, and the top surface of the flange 345 may be connected to the protrusions 346 in various ways described above in the exemplary embodiments of the present invention, such as, for example, via inclined, step and recess portions.

The protrusions 346 may be separated from one another as shown in FIG. 10. In this case, those of the protrusions 346 located at positions which correspond to corners of the optical sheet 50, may be wider than the other protrusions 346, which are formed between the corner positions. The protrusions 346 may be separated from one another by various distances. If the protrusions 346 are separated from one another as described above, the probability that the protrusions 346 are seen through the liquid crystal panel 31 can be significantly reduced.

The flange 345 may also be split into a plurality of flanges spaced apart from each other. Then, the protrusions 346 may be formed at respective ends of the flanges. The cross section of each of the protrusions 346 can be reduced by using the incline, step and recess configurations described above. An inclined portion or a step portion may be formed between each of the protrusions 346 and the flange 345. In addition, if the top and bottom surfaces of the protrusions 346 are formed on the same levels as those of the flange 345, respectively, a recess may be formed at an end of each of the protrusions 346.

Although the exemplary embodiments can be used as representative and independent embodiments, they can also be combined with one another. As described above, an LCD according to exemplary embodiments of the present invention can securely receive a liquid crystal panel and an optical sheet therein and prevent a dark area from being formed on the liquid crystal panel due to an intermediate frame.

While the present invention has been particularly shown and described with reference to exemplary embodiments thereof, it will be understood by those of ordinary skill in the art that various changes may be made therein without departing from the spirit and scope of the present invention as defined by the following claims.

What is claimed is:

1. A display device comprising:
a display panel;
a guide member comprising a plurality of sidewalls and a flange which extends from an inner surface of each sidewall, wherein the display panel is positioned on the flange; and
an optical sheet disposed under the flange,
wherein the flange comprises a top surface, which contacts the display panel, and a bottom surface which contacts the optical sheet, and the bottom surface of the flange extends further from the inner surface of each sidewall than the top surface of the flange.

2. The display device of claim 1, wherein the flange further comprises an inclined portion connecting the top surface and the bottom surface.

3. The display device of claim 1, wherein the flange further comprises a step portion between the top surface and the bottom surface.

4. The display device of claim 1, wherein the optical sheet comprises a diffusion sheet having a prism pattern formed thereon.

5. The display device of claim 1, wherein a thickness of the flange is reduced as the distance from the sidewalls is increased.

6. A display device comprising:
a display panel;
a guide member comprising a plurality of sidewalls and a flange which extends from an inner surface of each sidewall, wherein the display panel is positioned on the flange; and
an optical sheet disposed under the flange,
wherein the flange comprises a top surface, which contacts the display panel, and a bottom surface, which is opposite the top surface and contacts the optical sheet, and a recess formed between the top surface and the bottom surface toward each sidewall.

7. The display device of claim 6, wherein the top surface and the bottom surface of the flange extend the same distance from the inner surface of each sidewall.

8. The display device of claim 6, wherein the bottom surface of the flange extends further from the inner surface of each sidewall than the top surface of the flange.

9. The display device of claim 6, wherein the optical sheet comprises a diffusion sheet having a prism pattern formed thereon.

10. The display device of claim 6, wherein a thickness of the flange is reduced as the distance from the sidewalls is increased.

11. A display device comprising:
a display panel;
a guide member comprising a plurality of sidewalls and a plurality of flanges which protrude from inner surfaces of the sidewalls, respectively, wherein the display panel is positioned on the plurality of flanges; and
an optical sheet disposed under the flanges,
wherein the flanges are separated from one another by a predetermined gap.

12. The display device of claim 11, wherein a bottom surface of each flange extends further from the inner surface of each sidewall than a top surface of each flange.

13. The display device of claim 12, wherein each flange further comprises an inclined portion connecting the top and bottom surfaces.

14. The display device of claim 12, wherein each flange further comprises a step portion between the top and bottom surfaces.

15. The display device of claim 11, further comprising a diffusion sheet received under the flanges and having a prism pattern formed thereon.

16. The display device of claim 11, wherein a thickness of each flange is reduced as the distance from each sidewall is increased.

17. The display device of claim 11, wherein each flange comprises a top surface, which contacts the display panel, and a bottom surface, which is opposite the top surface, and a recess formed between the top surface and the bottom surface toward each sidewall.
